(19) United States
(12) Patent Application Publication
(10) Pub. No.: US 2001/0015490 A1
(43) Pub. Date: Aug. 23, 2001

(54) HIGH SPEED DIGITAL AND MICROWAVE DEVICE PACKAGE

(76) Inventor: HAI YOUNG LEE, SEOUL (KR)

Correspondence Address: COOPER & DUNHAM, 1185 AVENUE OF THE AMERICAS, NEW YORK, NY, 10036

(21) Appl. No.: 09/019,088

(22) Filed: Feb. 5, 1998

(30) Foreign Application Priority Data
May 22, 1997 (KR) 19918/1997

(51) Int. Cl. H01L 23/34; H01L 23/48; H01L 23/52; H01L 29/40

(52) U.S. Cl. 257/693; 257/690; 257/784

(57) ABSTRACT

High speed digital and microwave device package is disclosed, in which a dielectric with a relative permittivity of 3.5˜4.5 are buried on portions of bonding wire exposed to air in a packaging process for reducing a parasitic component and improving a match characteristic. An buried double bonding wires are analyzed by Method of Moment and compared to existing bonding methods. Particularly, as results of analysis of a permittivity of the dielectric (epoxy composite) by using Cole-Cole model which can take losses and changes in a wide frequency band into consideration, it is found that a parasitic reactance, at 20 GHz being 11Ω, shows a reduction by approx. 90%, 80% and 60% compared to a single bonding wire in air, double bonding wires in air and a ribbon bonding wire in air respectively. Though characteristic impedances of the single bonding wire in air, double bonding wires in air and ribbon bonding wire in air, being 235Ω, 133Ω and 98Ω respectively, shows greater mismatch characteristics compared to the 50Ω transmission line, the characteristic impedance of the double bonding wire buried in a dielectric of the present invention, being 60Ω, shows a great improvement in the match characteristic compared to the background art bonding wires. A return loss at 20 GHz is improved by 15 dB, 10 dB and 5 dB and an insertion loss is improved by 2.5 dB, 0.7 dB and 0.2 dB due to such a match characteristic improvement. Accordingly, the present invention applied to a high speed digital and microwave device package can minimize performance degradation which may be caused when packaged with bonding wires.

### BACKGROUND OF THE INVENTION

1. Field of the Invention

The present invention relates to a semiconductor package, and more particularly, to a high speed digital and microwave device package.

2. Discussion of the Related Art

The fast development of mobile communication and multimedia industries accelerates the advancement to an information oriented society, currently. And, development of a large capacity, very high speed communication system is underway for satisfactory high quality information service to users. Because of this, an importance on development of a highly integrated microwave semiconductor device for use in information and communication is emphasized, for which, not only design and fabrication technology of the semiconductor chip itself, but also the device packaging technology are prerequisite. Since the packaging technology up to now is for semiconductor chips of rather low density and speed, the researches have been conducted in view of mechanical and material. However, the fast increase of information amount to be processed by a semiconductor chip inevitably causes an increase of a device operation speed, with subsequent degradation of high speed signal transmission performance, coming from not only the semiconductor chip itself, but also external factors, such as external interconnections, packaging materials, form of the packaging and the like. In practice, a bonding wire, one of typical interconnections in the semiconductor chip, acts as a parasitic inductance, placing a major limitation on a high speed signal transmission performance of a device. Such a bondwire parasitic effect can be improved by means of multiple wire bonding, ribbon bonding, flip chip bonding and the like. In the multiple wire bonding, multiple bonding wires are connected in parallel for reducing a parasitic component and improving a high frequency transmission performance, but with not so great effect of reduction of the parasitic component due to the great mutual inductance caused by the small spacing between the wires. Even though the ribbon bonding has merits in current distribution and conductor resistance reduction compared to the bonding wire, it provides no flexibility in fabrication process, with a difficulty in automatization of the process and can give an excessive stress to the device during the bonding, with a possible drop of overall device performance. The flip chip bonding, with its very short interconnection length, has a small parasitic component, and particularly, finds its fields of application extended widely recently as it allows packaging with high device packaging densities, but only applicable to high density device packaging of micron modules.

In the meantime, the bonding wires, being transmission lines, may be defined of its equivalent characteristic impedance in a microwave frequency band and shows a mismatch characteristic due to the comparatively great characteristic impedance. A method of employing a flared lead strip is proposed for improving a high frequency signal transmission characteristic of wires caused by such a mismatch characteristic, in which a width of the lead strip to which the bonding wire is connected is made greater, to provide a capacitive component that can offset an inductive component of the bonding wire. However, since the capacitive component at the flared lead strip couples with the inductance of the wire, forming a resonant circuit, an effective reduction of a reflection loss in a wide frequency band can not be expected.

FIGS. 1a, 1b and 1c illustrate bonding wires in background art high speed digital and microwave device packages, wherein FIG. 1a illustrates a single bonding wire, FIG. 1b illustrates double bonding wires, and FIG. 1c illustrates a ribbon bonding wire, structures generally observed in MMIC (Monolithic Microwave Integrated Circuit) and hybrid microwave circuit. As shown, the bonding wire 3, bonded both on a bonding pad 2 on a substrate 1 and a lead strip 4, electrically connects an internal circuit to the substrate 1 to an external circuit 1 to the substrate 1. In this case, a metal ground plane 5 formed under the substrate 11 and the bonding wires 3.

However, the background art high speed digital and microwave device package has the following problems.

Being a line interconnecting a semiconductor chip and an external circuit, the bonding wire acts as a parasitic inductance, not only limiting a high speed transmission characteristic of a device, but also a mismatching characteristic.

### SUMMARY OF THE INVENTION

Accordingly, the present invention is directed to a high speed digital and microwave device package that substantially obviates one or more of the problems due to limitations and disadvantages of the related art.

An object of the present invention is to provide a high speed microwave device package which can reduce parasitic component of a bonding wire and improve a matching characteristic.

Additional features and advantages of the invention will be set forth in the description which follows, and in part will be apparent from the description, or may be learned by practice of the invention. The objectives and other advantages of the invention will be realized and attained by the structure particularly pointed out in the written description and claims hereof as well as the appended drawings.

To achieve these and other advantages and in accordance with the purpose of the present invention, as embodied and broadly described, the high speed microwave device package includes at least one bonding wire bonded to a circuit on a substrate of a packaged device for electric connection to circuits outside of the substrate, the bonding wire being buried in any one of epoxy, silicon, polyimide and urethane.

In other aspect of the present invention, there is provided high speed digital and microwave device package including at least one semiconductor chip, a plurality of bonding pads on the semiconductor chip, double bonding wires to correspond to each bonding pad for electric connection of the bonding wires to a corresponding bonding pad, a lead for electric connection of the double bonding wires to an external circuit, a dielectric selected from a group consisting of epoxy, silicon, polyimide and urethane for burring the double bonding wires, and a metal ground plane formed under the semiconductor chip and the double bonding wires.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention:

In the drawings:

FIGS. 1a, 1b and 1c illustrate bonding wires in background art high speed digital and microwave device packages;

FIGS. 2 illustrates bonding wires in a high speed digital and microwave device package in accordance with a preferred embodiment of the present invention;

FIG. 3a illustrates a graph showing input impedances according to a frequency of each bonding wire in packages of the present invention and background art calculated by moment method;

FIG. 3b illustrates a graph showing equivalent effective parasitic inductances in view of input according to a frequency of each bonding wire in packages of the present invention and the background art;

FIG. 4a illustrates a 50Ω smith chart showing input impedances according to a frequency of each bonding wire in packages of the present invention and the background art;

FIG. 4b illustrates a graph showing reflection coefficients S₁₁ for 50Ω lead strip on each bonding wire in packages of the present invention and the background art;

FIG. 4c illustrates a graph showing transmission coefficients S₂₁ for 50Ω lead strip on each bonding wire in packages of the present invention and the background art; and,

FIG. 5 illustrates a graph showing equivalent characteristic impedances when a width between wires and a permittivity of double bonding wires buried in a dielectric are varied in packages of the present invention.

### DETAILED DESCRIPTION OF THE PREFERRED EMBODIMENT

Reference will now be made in detail to the preferred embodiments of the present invention, examples of which are illustrated in the accompanying drawings. In the present invention, multiple bonding wires are incased in a dielectric, such as epoxy, silicon, polyimide, urethane, for reducing a parasitic component of the bonding wires and improving matching characteristic, for which the Method of Moment (MoM) is used for analyzing the bonding wires, and the results of the analysis are compared with characteristics of existing bonding methods. Particularly, Cole-Cole model, which can take into losses and variations in a wide band frequency account, is used in the permittivity analyzation of epoxy of the aforementioned dielectrics.

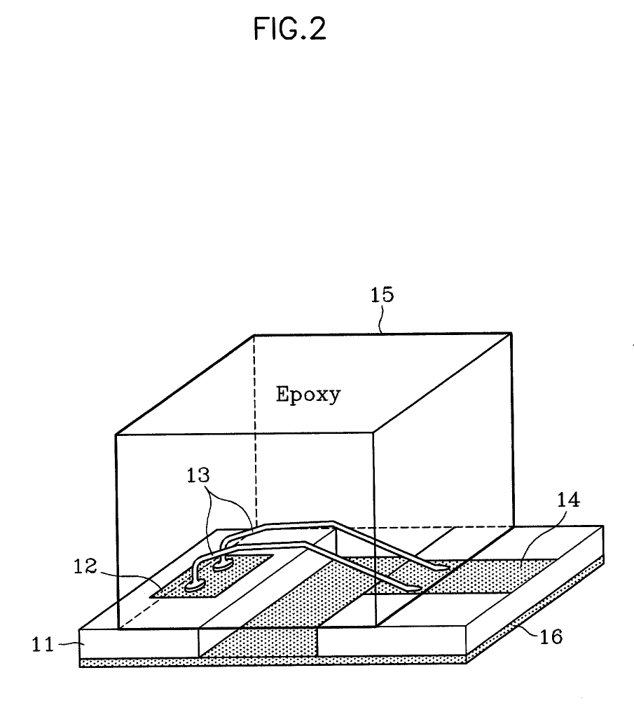

FIGS. 2 illustrates bonding wires in a high speed digital and microwave device package in accordance with a preferred embodiment of the present invention, wherein bonding wires 13 bonded on a bonding pad 12 on a substrate 11 and on a lead strip 14 connect an internal circuit of the substrate 11 to an external circuit of the substrate 11. In this case, a metal ground plane 16 formed under the substrate 11 and the bonding wires 13. The bonding wire 13 and a space around it is buried in dielectric 15 of an epoxy composite. The bonding wire 13 may be a single bonding wire or multiple bonding wires other than the double bonding wires shown in FIG. 2. In the case of multiple bonding wires, a space between adjacent bonding wires is set to be in a range of 150˜250 μm. The dielectric 15 for burring the bonding wire 13 may be selected from epoxy, silicon, polyimide and urethane, with a permittivity of 3.5˜4.5. The reason that a dielectric with a permittivity of 3.5˜4.5 are selected and the space between adjacent bonding wires is set to be in a range of 150˜250 μm will be explained, later.

The bonding wire is analyzed by the moment method for examining characteristics of the aforementioned high speed digital and microwave device package of the present invention. In general, polymer group epoxy composites is widely used as EMC (Epoxy Molding Compound) and PCB (Printed Circuit Board) due to its mechanical and electrical stability and low cost. In the analyzing using the moment method, a modeling of a permittivity of the epoxy composite involved in a wide band frequency is important for taking influences of the epoxy composite into consideration. The epoxy composite is formed of reinforcement, resin, and other additives. A permittivity of an epoxy composite representing an electric property of the epoxy composite can be expressed as a volummetric ratio of the reinforcement and the resin, as the following equation.

$$ε = {ε}_{0} {ε}_{r } = {ε}_{0} ( {ε}_{r}^{′} - j {ε}_{r}^{″} ) , \qquad ( 1 )$$

where, ε_{0, ε}ᵣ, ᵣε′ and ᵣε″ respectively represent a free-space permittivity, a relative permittivity, and a real term and an imaginary term of the relative permittivity. The real term of the relative permittivity, εᵣ′, is rapidly decreases at a frequency band centered on a maximum relaxation frequency fm. And, the imaginary term of relative permittivity, εᵣ″, denoting a dielectric loss resulted from a dielectric relaxation effect of a time-varying field, increases as the frequency increases and decreases after the maximum relaxation frequency fm. Such a change of complex relative permittivity can be expressed by the following Debye dispersion equation which is a typical permittivity model of a polymer;

$${ϵ}_{r} ( ω ) = {ϵ}_{∞} + \frac{{ϵ}_{s} - {ϵ}_{∞}}{1 + j ω τ} \qquad ( 2 )$$

where ω, ε_{S}, ε_{∞} and τ[=1/(2πfm)] represent frequency, a real term of permittivity at a low frequency (<<fm), a real term of permittivity at a high frequency (>>fm) and a polarization relaxation time. However, since the Debye equation can not take the dispersion effect coming from multiple relaxation effect of EMC (Epoxy Burring Compounds) which are composite polymer group materials, though expresses well about a single relaxation effect, the complex relative permittivity can be expressed as equation (3) shown below using the Cole-Cole model, being a modification of the Debye equation.

$${ϵ}_{r} ( ω ) = {ϵ}_{∞} + \frac{{ϵ}_{s} - {ϵ}_{∞}}{1 + {( jω τ )}^{α}} \qquad ( 3 )$$

where α is a disperse coefficient for taking the multiple relaxation effect into consideration, being 0≦α≦1. A permittivity of an epoxy composite modeled as the equation (3) is in the Method of Moment analysis for taking an influence of material to a signal transmission by bonding wire into consideration, more accurately. As a result of calculation of Cole-Cole model parameters for the epoxy composite which are in agreement to an actual measurement result, the ε_{S}, ε_{∞}, τ and α obtained for an epoxy composite with a resin of 72.4% by volume are 3.89, 4.71, 0.106 and 0.28, respectively.

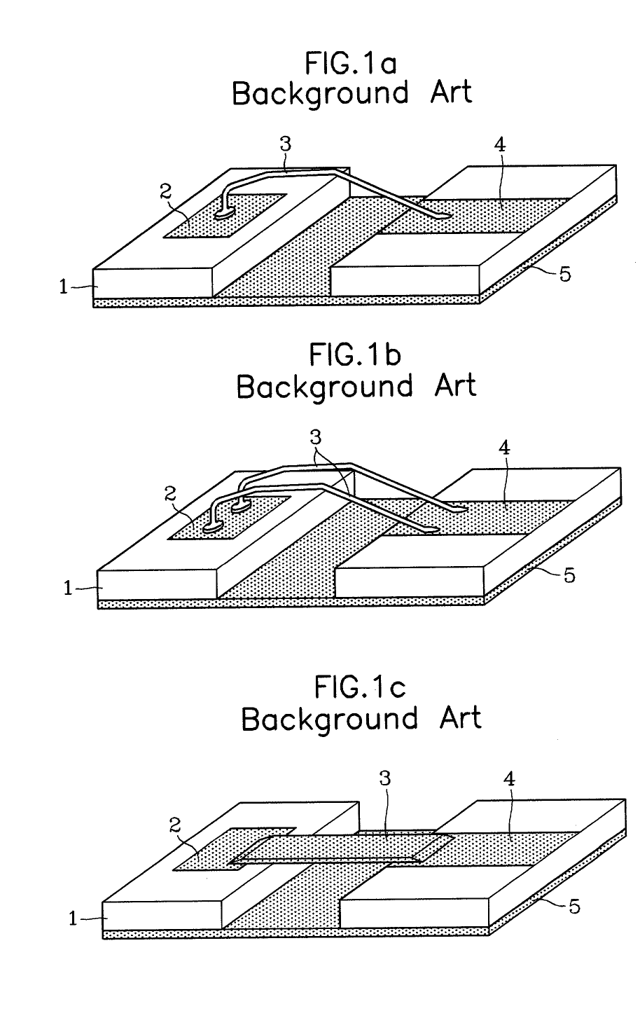

The different interconnections shown in FIGS. 1a, 1b, 1c and 2 are analyzed by the Method of Moment at a wide frequency band. In order to model a current on a bonding wire approximated as linearized-wires with little error, the wire is divided into lengths each longer than 1/32 times of a wavelength of an applied signal. And, in the case of ribbon bonding wire, in order to model a transverse current distribution adequately, the wire-grid model in which a ribbon is expressed as plural straight wires is used in the Method of Moment analysis. In the calculation of the Method of Moment, after each of the linearized-wires are linearly divided into secondary linearized-wires, currents thereon are developed into a pulse expansion function, and subjected to Galerkin's process using a pulse test function. For the convenience of the Method of Moment calculation, a static capacity of the bonding pad itself which is very small is neglected. Because substrate modes are occurred over 100 GHz, and radiation effect and substrate mode coupling effect of the bonding wire are very small, structures of the bonding wire at both ends thereof and a discontinuity effect of permittivity in the frequency range considered have been neglected. A diameter of the bonding wire, being 25 μm very small compared to a length of the wire or a wave length of the range of frequency considered, we can assume that there is only an axial current directed along the wire axis. An electromagnetic field scattered by unknown currents on the wire segments can be expressed by the free-space Green's function using Lorenz condition. By assuming that an electric field and a potential phase distributed at each pulse segment are constant at a secondary current pulse segment, the current expansion coefficients make possible to discretize the resulting integral equation at the each wire segment.

The equation digitized thus can be arranged into the known network equation of N×N square matrix form using the defined integrals (ωm, p, q).

[Z][I]=[V] (4),

where,

[I]=[I₁ I₂- - - Iₙ]^{T},

$$\begin{matrix}{Z}_{mn} = \frac{1}{j4 {πωϵ}_{0} {ϵ}_{r} ( ω )} ( \begin{matrix}{ω}^{2} {ϵ}_{0} {ϵ}_{r} ( ω ) {μ}_{0} [ {\vec{s}}_{m} \cdot {\hat{s}}_{n} ] {Ψ}_{m , n - \frac{1}{2} , n + \frac{1}{2}} - \\ \frac{1}{( {s}_{n + 1} - {s}_{n} )} [ {Ψ}_{m + \frac{1}{2} , n , n + 1} - {Ψ}_{m - \frac{1}{2} , n , n + 1} ] + \\ \frac{1}{( {s}_{n} - {s}_{n - 1} )} [ {Ψ}_{m + \frac{1}{2} , n - 1 , n} - {Ψ}_{m - \frac{1}{2} , n - 1 , n} ]\end{matrix} ) \\ Ψ m , p , q ≡ {\int }_{{s}_{p}}^{{s}_{q}} k ( {s}_{m} - {s}^{′} ) ⅆ {s}^{′}\end{matrix}$$

S_{I}=ith segment of the line integral

$$[ V ] = [ \begin{matrix}{\vec{E}}_{i} ( {s}_{1} ) \cdot \vec{{s}_{1}} & {\vec{E}}_{i} ( {s}_{2} ) \cdot \vec{{s}_{2}} & … & {( {\vec{E}}_{i} ( {s}_{m} ) \cdot \vec{{s}_{m}} ] )}^{T}\end{matrix}$$

The k(s-s′) is calculated by integrating the Green's function around entire wire as follows.

$$k ( s - {s}^{′} ) = \frac{1}{2 π} {\int }_{x}^{- x} \frac{{ⅇ}^{- j ω} \sqrt{{μ}_{0} {ϵ}_{0} {ϵ}_{r} ( ω ) r}}{r} ⅆ Φ \qquad ( 5 )$$

In the Method of Moment calculation, polarization and relaxation by dielectric with a little loss are taken into account using a complex permittivity ε=ε′−jε″, and a perfect ground plane is replaced with an image wire using the image theory.

An impedance of the bonding wire is calculated by dividing an applied voltage with an input current at the pad. Two currents I₁ and I₂ at connection points of the bonding wire with the bonding pad and the lead strip at both ends of the bonding wire can be extracted from results of the aforementioned Method of Moment calculation, and a scattering parameter S-parameter can be calculated from the currents I₁ and I₂. When the connection points of the bonding wire with the bonding pad and the lead strip are defined to be port 1 and port 2 respectively, there is no incident voltage V₂⁺ at port 2 because the characteristic impedance Z₁₂ of the lead strip, being 50Ω, is the same with the reference impedance. A return loss may be obtained using the following equation from the input impedance Zₘ₁ at the port 1.

$${( {( {( {S}_{11} = \frac{{V}_{1}^{-}}{{V}_{1}^{+}} \vert )}_{{Z}_{12} = 50} = {Γ}_{1} \vert )}_{{Z}_{12} = 50} = \frac{{Z}_{in1} - 50}{{Z}_{in1} + 50} \vert )}_{{Z}_{12} = 50} \qquad ( 6 )$$

In the meantime, an insertion loss can be calculated by the following equation (7) using voltage V₂ applied to the port 2 which is matched ₁₂Z=50Ω after matching the port 1 by connecting the port 1 to a driving power source as well as a driving power resistance Z₁₂=50Ω.

$${( {( {( {S}_{1} = \frac{{V}_{1}^{-}}{{V}_{1}^{+}} \vert )}_{{Z}_{12} = 50} = \frac{{V}_{2}}{{V}_{g} / 2} \vert )}_{{Z}_{12 } = 50} = \frac{2 {I}_{2} {Z}_{12}}{{V}_{g}} \vert )}_{{Z}_{12} = 50} \qquad ( 7 )$$

In order to know signal transmission characteristics, after a non-uniform transmission structure with partial differences of heights are approximated into uniform transmission line, an equivalent characteristic impedance Z₀ is obtained. As the considered bonding wire has very small ratios of height change compared to the length of the wire, with a very low non-uniformity of the characteristic impedance, a Quasi-TEM mode analyzation is possible. From the input impedance Zₘ₁ of the bonding wire obtained by the Method of Moment, an equivalent uniform characteristic impedance Z₀ may be obtained using the equivalent uniform transmission line equation, as follows.

$${Z}_{0} = \frac{1}{2} ( {Z}_{in1} - {Z}_{12} ) coth γ l + \sqrt{{( {Z}_{in1} - {Z}_{12} )}^{2} {coth}^{2} γ l + 4 {Z}_{in1}^{2} {Z}^{{2}_{12}}} , \qquad ( 8 )$$

where,

$$γ = j ω \sqrt{{ϵ}_{0} 0} \sqrt{{ϵ}_{r} - j {ϵ}_{r}}$$

Z₁₂, γ, 1 are a characteristic impedance of a lead strip, a complex transmission coefficient in a Quasi-TEM mode, and a shortest distance from the bonding pad to the lead strip connection point. Of the bonding wires shown in FIGS. 1a and 1b, ε′ᵣ and ε″ᵣ are taken as 1 and 0 in all the analyzed frequencies, respectively.

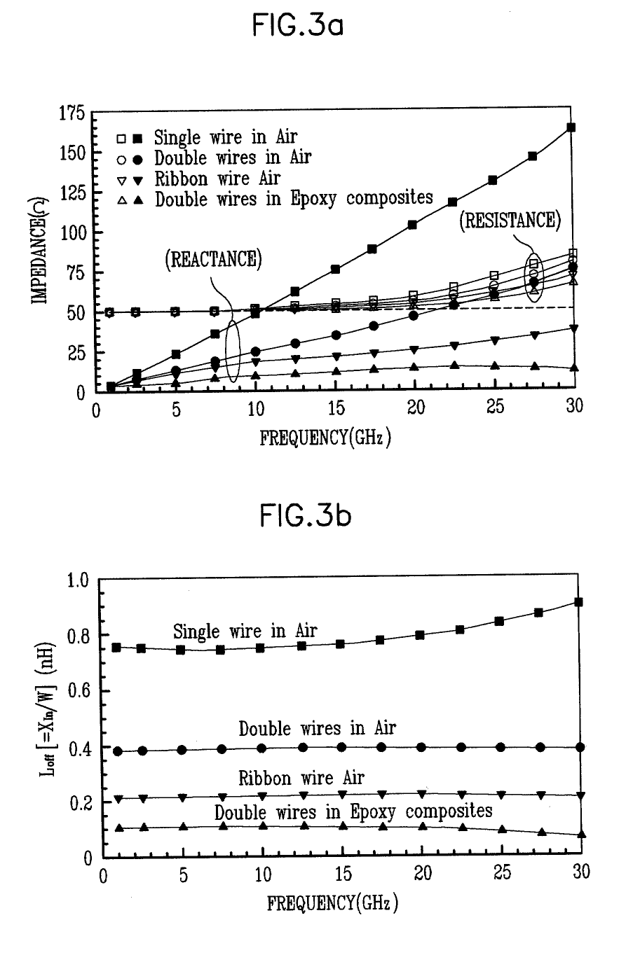

As results of such analyses, input impedances and effective parasitic inductances versus frequencies of the single bonding wire in air, double bonding wires in air, ribbon bonding wire in air of the background art shown in FIGS. 1a, 1b and 1c and the double bonding wire buried in an epoxy composite of the invention shown in FIG. 2 are calculated by the Method of Moment and illustrated in FIGS. 3a and 3b.

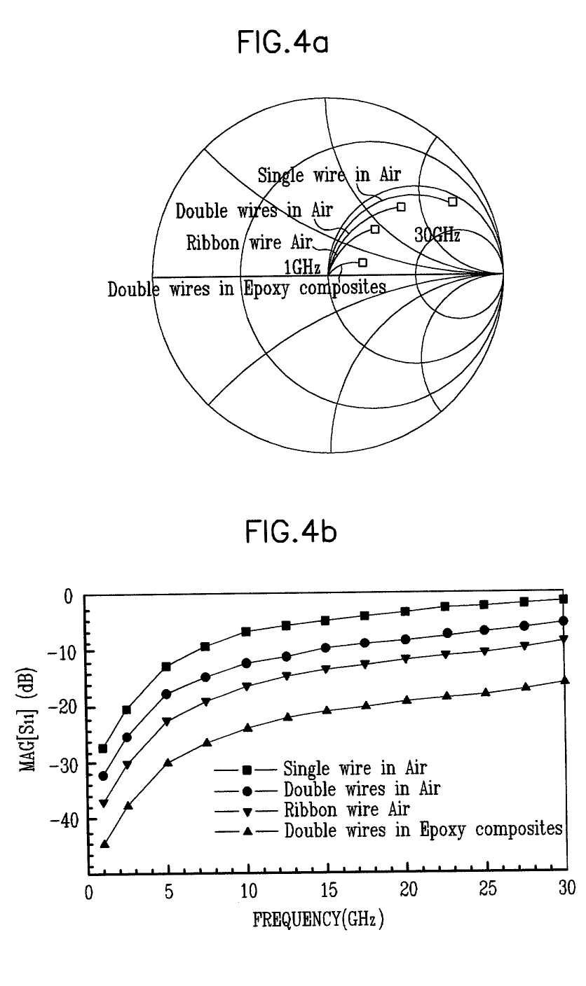

First, referring to FIG. 3a, it can be seen that both input resistance and input reactance are increased as frequency increases. It is found that an input reactance difference between a single bonding wire in air and buried double bonding wires is 150Ω at the maximum while input resistance differences between the four bonding wires at frequency of 30 GHz are 20Ω at the maximum, from which it can be known that electric characteristic differences of the four bonding wires come mostly from the input reactances. As the frequency increases, the input reactances are increased in the order of the single bonding wire in air, the ribbon bonding wire, the double bonding wire buried in an epoxy composite burring. Over the entire frequency range considered, it is confirmed that the input reactance of the double bonding wire buried in an epoxy composite is the minimum. The bonding of a dielectric burring application of the present invention exhibits reductions of input reactances of approx. 90%, 80% and 60% compared to the single, double and ribbon bondings, respectively. This reduction of reactance comes from the offset of an inductive reactance prevalent in current bonding wire by a capacitive reactance due to dielectric in a wide range of frequencies. And, it can be known from FIG. 3b that an effective parasitic inductance of the single bonding wire in air, being 0.8 nH at 20 GHz, acts as a significantly large parasitic component. Compared to this, it can be seen that the double bonding wires in air has an effect of 50% inductance reduction. It is observed that the effective parasitic inductance of the double bonding wire buried in the epoxy composite, being below 0.1 nH at all frequency ranges considered, shows a 50% reduction effect even compared to the ribbon wire which has an excellent electric performance. Shown in FIG. 4a is a 50Ω Z-Smith chart having the input impedances of the four bonding wires are plotted thereon for observation of relation with match characteristics. Since all the bonding wires involve an increase of electric length as a frequency increases, the input impedance rotates toward a source on the Smith chart. Though the mismatch characteristic can be ignored at below 1 GHz for all bonding structures, the parasitic input impedance increases as the frequency increases. In this instance, it can be known that the double bonding wire buried in the epoxy composite has the best match characteristic as it shows the least input impedance increase with the smallest rotation radius. Characteristic impedances of the different bonding wires are actually calculated by equation (4) and shown in TABLE 1 below. Though characteristic impedances of the single bonding wire in air, double bonding wires in air and ribbon bonding wire in air, being 235Ω, 133Ω and 98Ω respectively, shows greater mismatch characteristics compared to the 50Ω transmission line, the characteristic impedance of the double bonding wire buried in a dielectric of the present invention, being 60Ω, shows a great improvement in the match characteristic compared to the background art bonding wires.

TABLE 1
Frequency ranges with characteristic impedance and return loss below
−10 dB for different bonding wires

| | single | | ribbon | |
|---|---|---|---|---|
| | bonding | double bonding | bonding | buried double |
| | wire in air | wires in air | wire in air | bonding wires |
| characteristic | 235 | 133 | 98 | 60 |
| impedance(Ω) | | | | |
| return loss | ≦7 GHz | ≦14 GHz | ≦25 GHz | ≦30 Ghz |
| (≦−10 dB) | | | | |

Reflection coefficients S₁₁ and transmission coefficients S₂₁ of all bonding wires for 50Ω transmission line are shown in FIGS. 4b and 4c, respectively. It can be known from FIG. 4b that the double bonding wire buried in an epoxy composite, having a very small return loss below— 15 dB up to a frequency of 30 GHz, shows a very excellent match characteristic. The double bonding wire buried in an epoxy composite shows an effect of improvement of 15 dB, 10 dB and 5 dB compared to the single bonding wire in air, the double bonding wires in air and the ribbon bonding wire in air respectively due to the excellent match characteristic. It can be seen from FIG. 4c that the single bonding wire in air is involved in a great degradation of a signal transmission characteristic at a frequency above 25 GHz due to an insertion loss greater than − 3 dB. Alike the return loss, it can be known that the double bonding wire buried in an epoxy composite shows only a very small insertion loss of 0.2 dB at 25 GHz due to the excellent match characteristic. And, a range of frequency in which all the bonding wire structures show a return loss below −10 dB is shown in TABLE 1. It can be known that the double bonding wire buried in an epoxy composite of the present invention assures the best signal transmission performance in the widest frequency range.

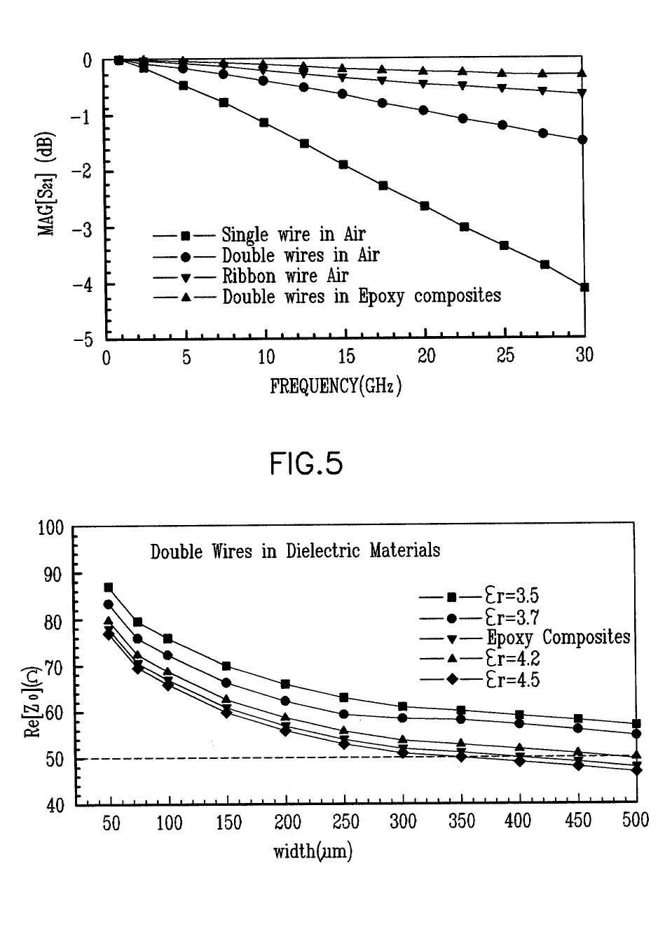

Finally, characteristic impedances calculated for different wire spaces (widths) of the double bonding wires buried in different dielectrics are shown in FIG. 5. The range of relative permittivity considered herein, being 3.5 to 4.5, is selected from relative permittivities of epoxies available for practical molding. And, it is found from FIG. 5 that the characteristic impedances are reduced at a fixed width as the relative permittivities increase due to increase of dielectric effect. And, it can be seen that the characteristic impedances increase as the spaces increase at a fixed relative permittivity. This is because of the reduction of a inductive reactance of the double bonding wires itself due to a reduction of mutual inductance coupling between wires as the space distances increase. It can be seen that there is an optimal bonding structure at which the 50Ω match is accomplished when the space distance is increased and a dielectric of a particular relative permittivity is used.

As has been explained, in the present invention, a structure in which a bonding wire is buried in a dielectric material is suggested as a method for reducing a parasitic component of an external connection line occurred when a microwave device is packaged and input impedance, characteristic impedance, electric characteristics of insertion and return losses at wide frequency band are analyzed using the Method of Moment. An epoxy composite is used as the dielectric material, and complex permittivities involved in frequency are modeled using Cole-Cole model. Current single bonding wire in air, double bonding wires in aire and ribbon bonding wire in air are analyzed as well and compared the results. As a parasitic reactance of the double bonding wire buried in an epoxy composite being 11Ω at 20 GHz frequency, showing that a reduction of parasitic reactance of the double bonding wire structure buried in a dielectric of the present invention of 89%, 78% and 58% compared to the single bonding wire, double bonding wires and ribbon bonding wire respectively, it is found that the double bonding wire structure buried in a dielectric of the present invention has the smallest parasitic component. And, it is observed that there is a significant improvement in match characteristic of the bonding wire structure of the present invention, which has a characteristic impedance of 60Ω, compared to other bonding wire structure. And, at a frequency below 25 GHz, the return loss is improved compared to the single bonding wire in air and the double bonding wires in air by 15 dB and 10 respectively and improved by 5 dB even to the ribbon bonding wire. From these, it can be known that the bonding wire buried in a dielectric material of the present invention applied to a microwave device package bonding wire for use in a frequency below 30 GHz can substantially improve a device external match characteristic and overall performance. The results of this analysis can be utilized in a microwave integrated circuit for connection between a chip pad and a lead, in a multichip module for connection between chips and connections in hybrid microwave circuit. Especially, the aforementioned method for reducing a parasitic effect of the bonding wire used in a high speed microwave device package of the present invention is applicable even to multichip modules in which a chip itself is replaced with one substrate having many semiconductor devices attached thereto. That is, bonding pads for monolithic integrated circuits on a substrate and micron conductive lines on a semiconductor substrate can be connected to provide a multifunctional semiconductor device. And, the present invention is applicable, not only to a bonding wire connecting between a chip and a lead strip on a package, but also to a bonding wire connecting a lead strip on a substrate and a conductive line on a housing, and applicable even to a bonding wire connecting a board and an external connector on a housing as well as to a construction in which chips which were not directly packaged are attached to patterns of a PCB, a printed substrate, and bonding pads of the chips and the patterns of the PCB are directly connected.

The aforementioned high speed microwave device package of the present invention has the following advantages.

The double bonding wire package buried in a dielectric has a parasitic reactance of 11Ω at a frequency of 20 GHz with reductions of reactances of approx. 90%, 80% and 60% compared to the single bonding wire in air, the double bonding wire in air and ribbon bonding wire in air, respectively.

Though characteristic impedances of the single bonding wire in air, double bonding wires in air and ribbon bonding wire in air, being 235Ω, 133Ω and 98Ω respectively, shows greater mismatch characteristics compared to the 50Ω transmission line, the characteristic impedance of the double bonding wire buried in a dielectric of the present invention, being 60Ω, shows a great improvement in the match characteristic compared to the background art bonding wires.

A return loss at 20 GHz is improved by 15 dB, 10 dB and 5 dB and an insertion loss is improved by 2.5 dB, 0.7 dB and 0.2 dB due to such a match characteristic improvement.

Accordingly, the present invention applied to a high speed digital and microwave device package can minimize performance degradation which may be caused when packaged with bonding wires.

It will be apparent to those skilled in the art that various modifications and variations can be made in the high speed digital and microwave device package of the present invention without departing from the spirit or scope of the invention. Thus, it is intended that the present invention cover the modifications and variations of this invention provided they come within the scope of the appended claims and their equivalents.

What is claimed is:

1. A high speed digital and microwave device package comprising:
a substrate;
at least one bonding wire bonded to a circuit on the substrate for electrically connecting the circuit on the substrate to circuits outside of the substrate;
a dielectric for burring the bonding wire; and,
a metal ground plane formed under the substrate and the bonding wire.

2. A high speed digital and microwave device package as claimed in claim 1, wherein the dielectric has a relative permittivity of 3.5˜4.5.

3. A high speed digital and microwave device package as claimed in claim 1, wherein the dielectric is any one of epoxy, silicon, polyimide and urethane.

4. A high speed digital and microwave device package comprising:
a semiconductor chip having a plurality of bonding pads;
at least one bonding wire to correspond to each bonding pad on the semiconductor chip for electric connection of the bonding wire to corresponding bonding pad;
a plurality of leads each for electric connection of the bonding wire to an external circuit;
a dielectric for burring the bonding wires; and,
a metal ground plane formed under the semiconductor chip and the bonding wire.

5. A high speed digital and microwave device package as claimed in claim 4, wherein the dielectric is any one of epoxy, silicon, polyimide and urethane.

6. A high speed digital and microwave device package as claimed in claim 4, wherein the dielectric has a relative permittivity of 3.5˜4.5.

7. A high speed digital and microwave device package as claimed in claim 4, wherein the semiconductor chip is a chemical semiconductor chip.

8. A high speed digital and microwave device package as claimed in claim 4, wherein the bonding wire is any one of a single bonding wire, double bonding wires and a ribbon bonding wire.

9. A high speed digital and microwave device package as claimed in claim 7, wherein the double bonding wires have a 150˜250 μm space between the wires.

10. A high speed digital and microwave device package comprising:
a plurality of semiconductor chips;
a plurality of bonding pads on each of the semiconductor chips;
at least one bonding wire to correspond to each bonding pad for electric connection of the bonding wire to a corresponding bonding pad;
a plurality of leads each for electric connection of the bonding wire to an external circuit;
a dielectric for burring the bonding wires; and,
a metal ground plane formed under the semiconductor chip and the bonding wire.

11. A high speed digital and microwave device package as claimed in claim 10, wherein the dielectric is any one of epoxy, silicon, polyimide and urethane.

12. A high speed digital and microwave device package as claimed in claim 10, wherein the dielectric has a relative permittivity of 3.5˜4.5.

13. A high speed digital and microwave device package as claimed in claim 10, wherein the bonding wire is any one of a single bonding wire, double bonding wires and a ribbon bonding wire.

14. A high speed digital and microwave device package as claimed in claim 13, wherein the double bonding wires have a 150˜250 μm space between the wires.

15. A high speed digital and microwave device package comprising:
at least one semiconductor chip;
a plurality of bonding pads on the semiconductor chip;
double bonding wires to correspond to each bonding pad for electric connection of the bonding wires to a corresponding bonding pad;
a lead for electric connection of the double bonding wires to an external circuit;
a dielectric selected from a group consisting of epoxy, silicon, polyimide and urethane for burring the double bonding wires; and,
a metal ground plane formed under the semiconductor chip and the double bonding wires.

16. A high speed digital and microwave device package as claimed in claim 15, wherein the dielectric has a relative permittivity of 3.5˜4.5.

17. A high speed digital and microwave device package as claimed in claim 15, wherein the double bonding wires have a 150˜250 μm space between the wires.
